(19) United States
(12) Patent Application Publication
(10) Pub. No.: US 2004/0211456 A1
(43) Pub. Date: Oct. 28, 2004

(54) Apparatus, system, and method of diagnosing individual photovoltaic cells

(76) Inventors: Jacob E. Brown, Corona del Mar, CA (US); Teodor M. Galitev, Fountain Valley, CA (US); Glen Long, Bloxon, VA (US)

Correspondence Address: MORGAN LEWIS & BOCKIUS LLP, 1111 PENNSYLVANIA AVENUE NW, WASHINGTON, DC, 20004, US

(21) Appl. No.: 10/612,891

(22) Filed: Jul. 7, 2003

Related U.S. Application Data
(60) Provisional application No. 60/393,379, filed on Jul. 5, 2002.

(51) Int. Cl. H01L 25/00; F16M 11/00

(52) U.S. Cl. 136/243; 248/163.1

(57) ABSTRACT

An apparatus, system and method of evaluating performance of a photovoltaic array that includes a plurality of photovoltaic elements. The function of each of the photovoltaic elements is to convert solar energy to electricity. The method includes diagnosing independently the functioning of individual photovoltaic elements, and identifying under-performing individual photovoltaic elements within the photovoltaic array. The diagnosing includes a separate diagnostic circuit for each of the individual photovoltaic elements, and the identifying includes analyzing contemporary and historical measurements of the individual photovoltaic elements.

### CROSS-REFERENCE TO RELATED APPLICATIONS

This application claims the benefit of the earlier filing date of U.S. Provisional Application No. 60/393,379, filed 5 Jul. 2002, the enitirety of which is incorporated by reference herein.

### FIELD OF THE INVENTION

Systems for converting solar energy to electrical energy often include a set of photovoltaic cells, a.k.a. “solar cells,” which are mounted on a common base and are electrically interconnected. Such a set of cells can be referred to as a photovoltaic module. It is frequently the case that pluralities of these modules are used together to obtain a desired electrical output, i.e., a specified voltage and current. Inasmuch as these modules are often mounted on top of buildings, it is desirable to provide convenient apparatuses, systems, and methods to install and service the modules.

### BACKGROUND OF THE INVENTION

It is believed that known systems of photovoltaic modules suffer from a number of disadvantages, including requiring an electrician or specialized solar technician, while working on a roof with live power since there is no way to turn off the solar energy source during daylight hours, to disassembly the known systems to troubleshoot failed components. If a single photovoltaic module fails in a system that includes many photovoltaic modules, that failure may not be realized until multiple photoyoltaic modules have failed or a complete system failure occurs.

During installation of known systems, each individual photovoltaic module is checked with a voltmeter for proper output and then connected to the system. However, a failure can occur after the time that the photovoltaic module is initially checked, e.g., as a result of a faulty connection to the rest of a string of photovoltaic modules. Thus, another disadvantage of these known systems is that, voltage and current measurements on the entire system, as-assembled, may not detect the faulty connection introduced at the time of installation.

During the manufacturing process of known systems, each individual photovoltaic module is connected to a voltmeter or other voltage measuring device to test the proper operation of the photovoltaic module. Thus, another disadvantage of these known systems is that this testing is time consuming and may not be accurate due to measurement errors.

Further, it is believed that all of the known setups for monitoring photovoltaic systems monitor either the direct current supplied by the entire system to an inverter or the alternating current power output of the entire system. Thus, a disadvantage of these known setups is that no information is given about the individual photovoltaic modules.

It is believed that there is a need to overcome the disadvantages of the known systems of photovoltaic modules.

### SUMMARY OF THE INVENTION

According to the present invention, a photovoltaic module includes a diagnostic feature such that, within an array of the photovoltaic modules, an under-performing photovoltaic module is individually identifiable for servicing, e.g., removal and replacement. Moreover, the identification can be done with out disconnecting or disassembling any part of the array of photovoltaic modules. Thus, it is possible according to the present invention to simplify and speed up the identification, removal, and replacement of under-performing photovoltaic modules, and thereby reduce the amount of time spent on the top or sides of a structure, e.g., a building, while performing these tasks.

The present invention provides an apparatus for diagnosing an under-performing photovoltaic element. The function of the photovoltaic element is to convert solar energy to electricity, and the photovoltaic element includes a face that receives the solar energy. The apparatus includes a by-pass diode that is electrically connected in parallel with the photovoltaic element, and an indicator that is electrically coupled to the by-pass diode. The by-pass diode operates between first and second states. The first operating state of the by-pass diode corresponds to a functional condition of the photovoltaic element, and the second operating state of the by-pass diode corresponds to a dysfunctional condition of the photovoltaic element. The indicator includes first and second modes. The first mode of the indicator signifies the first operating state of the by-pass diode, and the second mode of the indicator signifies the second operating state of the by-pass diode.

The present invention also provides a apparatus for diagnosing an under-performing photovoltaic element. The function of the photovoltaic element is to convert solar energy to electricity. The apparatus includes an electricity sensing device connected to the photovoltaic element and an indicator electrically coupled to the device. The electricity sensing device detects a voltage condition of the photovoltaic element. The indicator includes first and second modes. The first mode of the indicator signifies a functioning state of the photovoltaic element, and the second mode of the indicator signifies a functioning state of the photovoltaic element having not been achieved.

The present invention also provides a photovoltaic module that is to be mounted on a structure. The photovoltaic module includes first and second module faces and an edge that extends between the first and second module faces, a plurality of photovoltaic cells being commonly supported by a base, and a device connected to one of the plurality of photovoltaic cells and operating between first and second states. The first module face receives solar energy and the second module face generally confronts the structure. Each of the photovoltaic cells converts the solar energy to electricity. And the first operating state of the device corresponds to a functional condition of the at least one of the plurality of photovoltaic cells, and the second operating state of the device corresponds to a dysfunctional condition of the at least one of the plurality of photovoltaic cells.

The present invention also provides a system for diagnosing a photovoltaic array. The photovoltaic array includes a plurality of photovoltaic elements, the function of which is to convert solar energy to electricity. The system includes first and second by-pass diodes, and first and second diagnostic circuits. The first by-pass diode is electrically connected in parallel with a first one of the plurality of photovoltaic elements, and operates between first and second states. The first operating state of the first by-pass diode corresponds to a functional condition of the first photovoltaic element, and the second operating state of the first by-pass diode corresponds to a dysfunctional condition of the first photovoltaic element. Similarly, the second by-pass diode is electrically connected in parallel with a second one of the plurality of photovoltaic elements, and also operates between first and second states. The first operating state of the second by-pass diode corresponds to a functional condition of the second photovoltaic element, and the second operating state of the second by-pass diode corresponds to a dysfunctional condition of the second photovoltaic element. The first diagnostic circuit is electrically coupled to the first by-pass diode, and includes first and second modes. The first mode of the first diagnostic circuit signifies the first operating state of the first by-pass diode, and the second mode of the first diagnostic circuit signifies the second operating state of the first by-pass diode. Similarly, the second diagnostic circuit electrically coupled to the second by-pass diode, the second diagnostic circuit including first and second modes, the first mode of the second diagnostic circuit signifying the first operating state of the second by-pass diode, and the second mode of the second diagnostic circuit signifying the second operating state of the second by-pass diode.

The present invention also provides a method of evaluating performance of a photovoltaic array that includes a plurality of photovoltaic elements. The function of each of the photovoltaic elements is to convert solar energy to electricity. The method includes diagnosing independently the functioning of individual photovoltaic elements, and identifying under-performing individual photovoltaic elements within the photovoltaic array. The diagnosing includes a separate diagnostic circuit for each of the individual photovoltaic elements, and the identifying includes analyzing contemporary and historical measurements of the individual photovoltaic elements.

The present invention also provides a method of monitoring individual performance of each of a plurality of photovoltaic elements. Each of the plurality of photovoltaic elements function to convert solar energy to electricity. The method includes evaluating individually a status of each of the plurality of photovoltaic elements, communicating the status of each of the plurality of photovoltaic elements, and analyzing performance of each of the plurality of photovoltaic elements.

### BRIEF DESCRIPTION OF THE DRAWINGS

The accompanying drawings, which are incorporated herein and constitute part of this specification, illustrate presently preferred embodiments of the invention, and, together with the general description given above and the detailed description given below, serve to explain features of the invention.

FIG. 1 is a schematic illustration of a grid-tie solar electric system according to a preferred embodiment of the present invention.

FIG. 2 is a schematic depicting a wiring diagram for a grid-tie solar electric system according to a preferred embodiment of the present invention.

FIG. 3 illustrates an array of four photovoltaic modules according to a preferred embodiment of the present invention.

FIG. 4 is a detail view of the “Viewed Area” indicated in FIG. 3.

FIG. 5 is an exploded perspective view of a plug connector according to a preferred embodiment of the present invention, including one view of a male plug connector and two views from opposite ends of a female plug connector.

FIG. 6A is a schematic illustration of a first preferred embodiment for monitoring photovoltaic module performance using visual identification.

FIG. 6B is a schematic illustration of a second preferred embodiment for monitoring photovoltaic module performance using visual identification.

FIG. 7A is a schematic illustration of a low voltage system according to a preferred embodiment of the present invention.

FIG. 7B is a schematic illustration of a high voltage system according to a preferred embodiment of the present invention.

FIGS. 8A-8C illustrate a preferred embodiment for digitally monitoring photovoltaic module performance.

### DESCRIPTION OF PREFERRED EMBODIMENTS

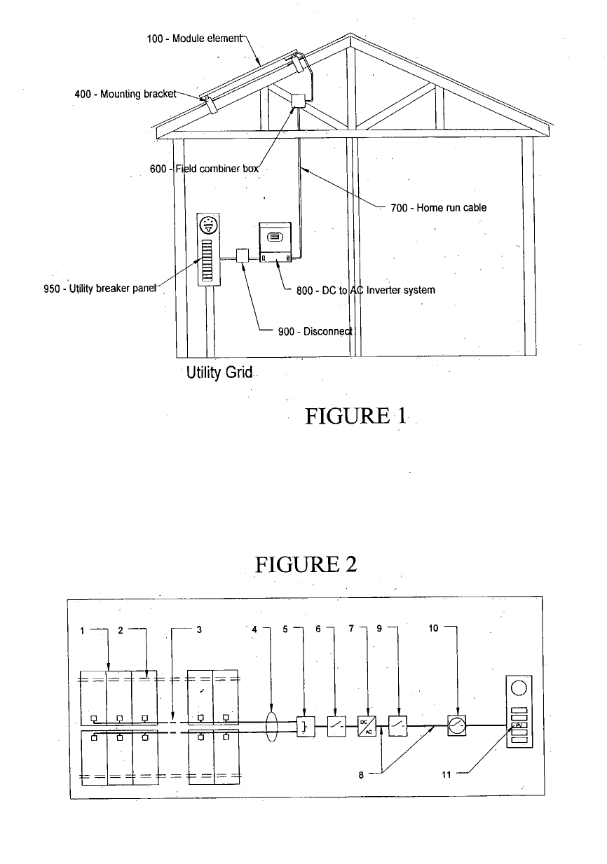

FIG. 1 shows an example of a grid-tie solar electric system according to a preferred embodiment of the present invention. These systems allow development of a pre-engineered and approved solar electric system package. A solar electric system package will consist of all components needed for a complete and easy installation of the photovoltaic system. For example, pluralities of solar electric modules 100 are secured via a mounting system 200 to a structure, e.g., a building. A field combiner box 600 electrically connects the outputs of at least some of the solar electric modules 100. One or more home run cable(s) 700 electrically couples the field combiner box(es) 600 to an inverter 800. And a utility disconnecting device 900 electrically connects and disconnects the inverter 800 with respect to a breaker panel 950 for the structure.

Referring to FIG. 2, a photovoltaic module 1 generates electricity and constitutes the primary building block of a photovoltaic system. A mounting system 2 includes the mounting hardware that is required to support the photovoltaic module 1 with respect to a structure, e.g., a roof of a building. Various cables, flexible conduits and cable trays 3 provide the connections between plural ones of the photovoltaic modules 1. Field cables and conduits 4 connect a single photovoltaic module 1 to a direct current to alternating current inverter 7. Alternatively, a combiner box 5 may be used to combine the outputs of plural photovoltaic modules 1, and then output the combined outputs to the inverter 7 via the field cables and conduits 4. A direct current disconnect 6 is located upstream of the inverter 7. Alternating cables 8 connect the output of the inverter 7 to a system breaker 11 in a breaker panel. An alternating current disconnect 9 and a lockable disconnect or four jaw meter base 10 may be located between the inverter and the system breaker 11.

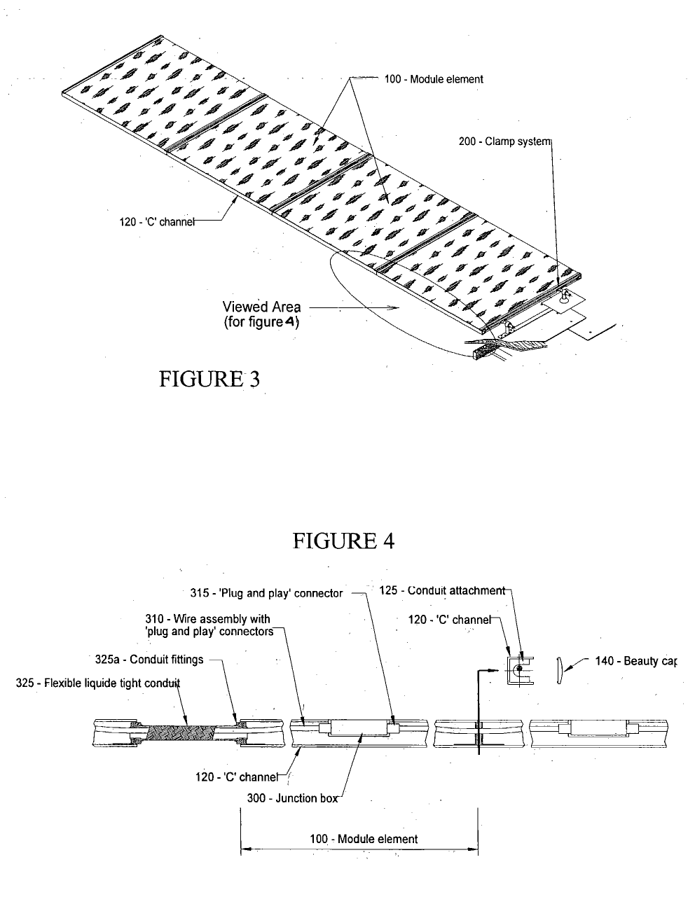

Referring to FIG. 3, a preferred array is shown that includes four modules elements 100 that are mounted using the clamping system 200. The clamp system 200 is used to securely mount a module element 100 to an installation surface, e.g. a roof of a building. The clamp system 200 is accessible from the visible top of the panel elements 100 and provides an easy assembly or disassembly using only human hand force. The array of module elements 100 can be arranged either horizontally or vertically: the modules can each have ‘C’ shaped channels 120 that are aligned so as to provide a wire raceway that runs the lengths of the module array, as shown in FIG. 3. After making all required electrical connections, a beauty cap cover 140 can be installed, to enclose the channels and thereby prevent severe environmental conditions from adversely affecting the wiring running in the ‘C’ channel.

Referring additional to FIG. 4, at approximately the midpoint of the ‘C’ shaped channels 120, a junction box 300 can be provided for enclosing the electrical connections. A wire assembly 310 completes the electrical circuit of the system. Each module will have at least one wire assembly 310. The wire assembly 310 can use three conductors, e.g., stranded copper from AWG 12 to AWG 6, THHN or THWN. The wire assembly 310 can have a jacket that is UV resistant, e.g., types US, USE or UF. The three conductors will be positive, negative and ground. Each wire assembly 310 can have a pre-attached plug connector 315 on each end. The plug connector 315 is a one-way, touch safe plug. The plug connector 315 will pass UL1703 tests and be NEC compliant. Male and female components are connected to form the plug connector assemblies. Preferably, female receptacles will be in the junction box 300, field combiner box(es) 600 and inverter box 800 and the wire assemblies 310 will have male ends. A female-to-female connector can also be provided to connect two male ends and extend the pre-assembled wire assemblies 310.

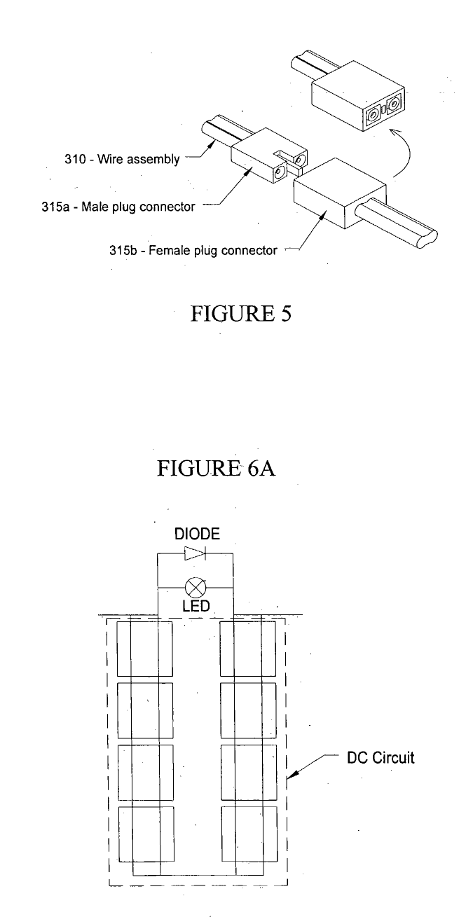

FIG. 5 shows a preferred embodiment of the plug connector 315, which includes a male plug connector 315a and a cooperatively mating female plug connector 315b. The plug connector 315 may be “plug and play” type, e.g., may include polarized male 315a and female 315b multiple conductor connectors that facilitate quick and easy connection and disconnection in a single possible relative orientation, and without the use of tools. This is in contrast to conventional wire nuts, soldered connections, etc. that are difficult to use in the environments in which the module elements 100 are frequently located.

According to the preferred embodiments of the present invention, the photovoltaic electrical wiring system provides an electrical circuit that electrically couples all of photovoltaic components together, provides a weather proof, secure and safe method of completing the electric circuit of a solar electric system, and includes positive, negative and ground connections.

The photovoltaic system wiring will be simplified with the use of pre-assembled wiring assemblies 310 consisting of wires and male plug connectors 315a/female plug connectors 315b that fit into their respective counterparts in the solar electric photovoltaic system. Thus, the wiring assemblies 310 can connect the junction boxes 300 located on the module elements 100, can connect the module frame to the module frame connection points, can connect ‘in-line’ to extend the wire lengths, can connect the combiner boxes in the photovoltaic system, and can connect into the inverter.

The plug connector 315 uses a three-conductor wiring system designed to be plugged in one direction, i.e., to eliminate cross-polarized connections. The three conductors are positive (+), negative (−), and ground leads. All conductors and connections will have the protection from the elements such as—water, e.g., moisture, sunlight resistant, e.g., UV, heat resistant, e.g., will keep connection intact even at high temperature, dust particles and condensation. Also the connections will provide a safe and easy installation such as-one way plug only, ground connection will be make first and break last, electrical spark free connect and disconnect, interlocking between male and female plugs for the appropriate strain relief of the connections.

The plug connector 315 and clamping system 200 are particularly advantageous in expediting the replacement of underperforming or failed photovoltaic modules 100. According to the present invention, it is also possible to immediately and precisely identify which one(s) of a plurality of photovoltaic modules 100 are underperforming or failed, due to, for example, an electrical short. In the absence of any protection, an electrical short will want to consume all available electric power. The energy of the electric power will be transformed into heat via the resistive load, resulting in a “hot spot” that can cause melting of encapsulating plastic and a high probability of fire damage. A by-pass diode 350 can protect a circuit or a photovoltaic module 100. The by-pass diodes 350 are installed in parallel and are properly sized (for a given amperage) such that the by-pass diode 350 will close and the current will by-pass the faulty cells or circuits.

A monitoring device according to the present invention monitors and identifies problems within the direct current circuit of a photovoltaic cell/string/module, or other solar product, based on changes in voltage, resistance or polarity. According to a preferred embodiment an electricity sensing device can be connected to the photovoltaic element for detecting a voltage condition of the photovoltaic element that is indicative of the photovoltaic element is functioning or is not functioning as expected. A problem can be pinpointed according to the present invention using either an “analog” method or a “digital” method. The logic behind both methods is the same: a diagnostic system will monitor voltage (e.g., measured in direct current Volts or milli-Volts) and polarity of each photovoltaic module 100. A fault indication can be analyzed visually (the analog method) or via computer (the digital method). System power (e.g., measured in Watts) can also be monitored according to the digital method.

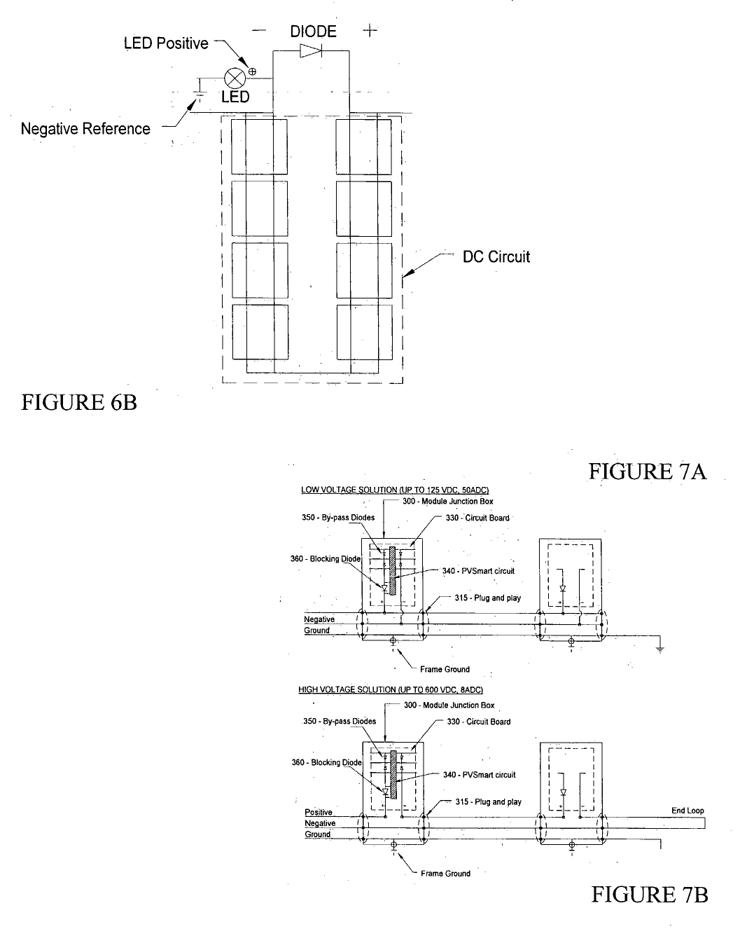

According to a preferred embodiment illustrated in FIG. 6A, a first analog or “visual identifier” method will now be described. A light emitting diode can be connected across the by-pass diode 350, and in case of failure will turn OFF. The light emitting diode provides visual identification and can be mounted in a convenient location, e.g., remotely, or laminated within the photovoltaic module itself. The light emitting diode will nominally be constantly ON (illuminated) and in case the direct current circuit fails the light emitting diode will turn OFF.

According to a preferred embodiment illustrated in FIG. 6B, a second analog or “visual identifier” method will now be described. A light emitting diode turns ON only in case of a direct current circuit failure. The light emitting diode is polarity sensitive and will only switch ON if the polarity matches between the positive leg of the light emitting diode and the negative reference. In case the bypass diode is activated by a failure, the polarity on both side of the diode will be positive and the light emitting diode will turn ON. The negative reference can be the module negative output or the photovoltaic system ground. The light emitting diode will be ON if the module is operating in an open circuit situation, indicating no output from DC circuit/module.

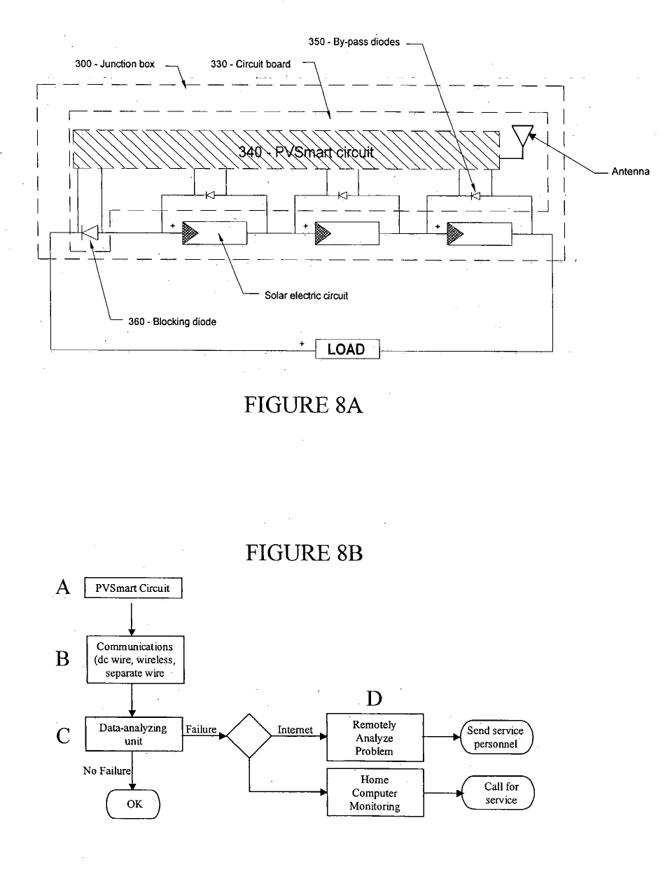

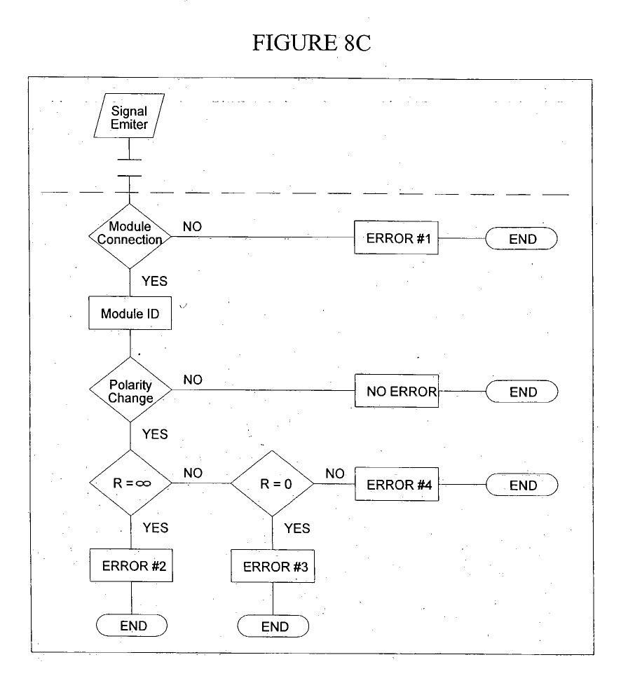

Referring to FIGS. 7A-8C, a digital method according to preferred embodiments of the present invention will now be described. FIG. 7A shows a preferred embodiment of junction box 300 line diagram for a low voltage system, e.g., up to 125 VDC, and FIG. 7B shows a preferred embodiment of junction box 300 line diagram for a high voltage system, e.g., up to 600 VDC. Each of these preferred embodiments of the present invention include features that evaluate the photovoltaic performance of an individual module 100, and uniquely identify an under-performing module among a plurality of modules 100. These features can include a circuit that may be embodied in the form of an integrated circuit chip associated with each photovoltaic module 100. Each circuit transmits an output signal, e.g., a digital signal, that is coded so as to be individually identifiable, and that contains information about the performance of the corresponding module. A reader, e.g., a personal digital assistant, receives the output signal and evaluates the performance of the modules. Thus, it is possible to quickly identify which one of the plurality of modules 100 needs service.

FIGS. 8A-8C illustrate a preferred embodiment of a digital method for monitoring and reporting on the operation of the electric circuits in an individual photovoltaic module 100, on the electrical performance of individual photovoltaic modules 100, and on the electrical performance of the entire solar electric system. Preferably, the digital monitoring system includes two main parts: the diagnostic circuit 340 and a data-analyzing unit 390.

Preferably, the diagnostic circuit 340 will be a single component, e.g., an integrated circuit such as a multi-leg logical circuit. The integrated circuit will also have sub-circuits for identification, measurement, and transmission. The identification circuit can include a unique digital identification number that is recorded onto the identification circuit. The measurement circuit can measure electrical performance on multiple external electrical circuits. And the transmission circuit can transmit the digital identification number and the digital equivalent of measured electrical performance data. The transmission circuit can transmit a signal via a dedicated signal wire, existing wires (DC or AC) or via radio frequency transmission to the external data-analyzing unit 390. Preferably, the diagnostic circuit 340 can be small enough to be laminated into the photovoltaic module 100 or be mounted in the module's junction box 300 or external housing.

Referring particularly to FIG. 8A, a diagnostic circuit 340 according to a preferred embodiment of the present invention can included a single integrated circuit chip on a power distribution printed circuit board that is installed in the junction box 300. An antenna for a transmitter can be a trace etched onto the printed circuit board. Shown in FIG. 8A are three by-pass diodes 350—one for each string in a photovoltaic module 100, i.e., for this example, there are three separate strings of solar cells that constitute the photovoltaic module 100. The module connection points are the connection points from the individual strings to the module connector in the junction box 300.

According to a preferred embodiment of the present invention, a diagnostic circuit 340 can be based on microprocessor technology. The front end can be a 10-bit analog-to-digital converter that is connected across each by-pass diode 350 to measure the voltage of each string of the photovoltaic module 100. Preferably, the voltage is conditioned to a nominal 5-volt signal before being presented to the analog-to-digital converter.

According to a preferred embodiment of the present invention, software for the diagnostic circuit 340 may be contained in read only memory on the integrated circuit chip. As the analog-to-digital channel for each string is sampled each time through a processing loop, the 0-5 volt input is scaled back to actual voltage levels based on the conditioning algorithm for each signal. The software then stores this number and samples the next channel. Once all of the channels have been sampled, the software calculates a time slot for transmission. The time slot is derived from the unique serial number that is assigned during production of the integrated circuit chip. This serial number is also the serial number of the module. The last three digits in the serial number can be used as the offset for the time slot, which allows for 10,000 unique time slots. Once a time slot is determined, the microprocessor continues to collect data until the time slot occurs. During the allocated time slot the microprocessor begins to send data, e.g., via radio frequency transmission, to a data collection system. Transmissions occur every about once every minute, so if there is a missed transmission the data will be repeated in the next time slot. Once the data is sent, the data buffer is discarded and the process is repeated.

To allow each unit to report over the same radio frequency channel, a time domain multiple access (TDMA) scheme may be used according to a preferred embodiment of the present invention. In particular, the unique serial number that is assigned to each photovoltaic module 100 will predefine a time slot to be used in the TDMA scheme. Time will be divided into segments allowing each photovoltaic module 100 to report its data. The microprocessor can be powered by its respective photovoltaic module. Thus, if a photovoltaic module 100 does not report any data, this will indicate that the photovoltaic module 100 has failed. Time can be started at the moment each string receives power since all of the photovoltaic module 100 will receive sunlight and begin providing electrical power at substantially the same time. This eliminates the need for each module to have a real-time clock.

Preferably, the external data-analyzing unit 390 will include a receiver circuit, a data analyzing algorithm, a data storage circuit, and a data transmission circuit. The receiver circuit will receive all signals emitted by the diagnostic circuits 340, identify the diagnostic circuits 340, and attach the corresponding digital equivalent measurement signal into a record (series of bits/bytes). The receiver circuit can be set to receive signals either at predetermined intervals of time or continuously. The receiver will create records from one or multiple diagnostic circuit(s) 340 at a time. The data analyzing algorithm will transform the data record to basic individual measurements and compare the data to previously analyzed and recorded measurement results. The data storage circuit will record and store information including identification numbers and the results from the circuit(s) analyzed. And the data transmission circuit will transmit the stored data to a central data storage location, e.g., via a telephone line, the internet, or wirelessly, e.g., by radio frequency transmission, to a remote location. The phrase “remote location” is defined as being spaced external to the photovoltaic module., The data-analyzing unit 390 can be mounted permanently at a specified location or can be a mobile device, e.g., a handheld unit such as a personal digital assistant.

According to a preferred embodiment of the present invention, the data collection system can be based on microprocessor technology. Preferably, a receiver that is integrated on a single chip can receive the radio frequency signal(s) transmitted from a diagnostic circuit 340. The receiver demodulates the signal and creates the original data stream for a microprocessor. The microprocessor processes the transmissions from each photovoltaic module 100 and stores the data in local memory, where it is kept until a connection to a host computer can be made. Options for host computer connection include: 1) directly to the system user's personal computer, or 2) via telecommunications. If the system user has a personal computer, then a direct connection can be made via a universal serial bus connection or via a RS-232 serial connection. The system user's personal computer would have data analysis software to provide local system status and power production statistics. Alternatively, if a personal computer is not available, a direct connection via a telephone system would allow the data collection system to send data directly to a central collection point, and no local processing would need to be done.

Central data collection allows for storage of long-term history data, which could be used to determine any degradation of system performance over long periods of time. This can find problems as subtle as a tree shading a photovoltaic installation or even leaves partially covering a photovoltaic module 100. Additionally, comparisons with other systems that are geographically close can be done automatically to determine overall system performance problems.

The operation of the digital monitoring system will now be described with particular reference to FIG. 8B. At the photovoltaic module 100 level “A,” the diagnostic circuit 340 will be connected to the electrical circuits of a photovoltaic module 100 for measuring voltage drop and voltage polarity of the module's circuits. The diagnostic circuit 340 will also measure the voltage drop of a known resistance connected to the output of the circuit. The diagnostic circuit 340 will then communicate “B” by transmit the measured data and the identification number to the external data-analyzing unit 390. This information can be communicated by: 1) wireless systems; 2) existing photovoltaic module 100 system wiring, e.g., +/−/ground; or 3) a dedicated signal wire that is separate from the system wiring. The communication network acts as a conduit to transmit the module identifier and the module-operating characteristic. At the external data-analyzing unit 390 level “C,” analysis and information transmission will occur. Preferably, a computational device, e.g., a personal digital assistant, will tabulate and store historical data from each photovoltaic module 100. This device will be able to determine if an individual module or the system is operating properly. Software “D” will monitor the photovoltaic module 100 and overall system activity including data such as weather conditions in regions where the photovoltaic modules 100 are installed. This data can be used, for example, to predict expected photovoltaic module and system electrical output, and allow rapid troubleshooting and problem repair.

The voltage that each photovoltaic module 100 reports may not be as important as the relative voltage from module-to-module when determining module status. As the day goes on the photovoltaic modules 100 will continue to report voltage generated. A series resistor can be installed to measure system current directly. System power can be directly calculated from the known system current and can also be sent in the data stream as another time slot.

According to the present invention, it is possible to identify a number of particular conditions that affect the performance of a photovoltaic module 100. These conditions can include: 1) shading of a photovoltaic module 100 or parts of the module; 2) module degradation and inconsistent operation; 3) obstructions that interfere with a photovoltaic module; and 4) failure, e.g., part or all, of a photovoltaic module 100.

The error operational logic of the diagnostic circuit 340, which is based on monitoring the by-pass diodes 350 in an electrical circuit of a photovoltaic module 100, will now be described with particular reference to FIG. 8C. Proper module function is indicated at “No Error.” A communication failure between the emitting device and the photovoltaic module 100 is indicated at “Error #1.” Failure of the by-pass diode 350 in an “open” state is indicated at “Error #2.” Failure of the by-pass diode 350 in a “closed” state is indicated at “Error #3.” And “Error #4” indicates that the diode 350 is by-passing a faulty or failed cell, string or module.

Thus, the present invention provides an integrated data acquisition system that allows real-time measurements of each individual cell, string, or photovoltaic module contained in a photovoltaic system. The system can be powered from a direct connection to the solar module, and data can be provided, e.g., telemetrically, to a collection point located on site. The data that is collected and analyzed locally and can also be sent to a central collection point for further processing.

A number of advantages are achieved according to the present invention. These advantages include providing a diagnostic tool that can determine if the system is working, if the system is performing as expected, if and where (e.g., which one of a plurality of photovoltaic modules 100) a malfunction is occurring, and determine the nature of the problem causing the malfunction. According to preferred embodiments of the invention, instantaneous evaluation of system performance can be diagnosed visually at the photovoltaic modules 100 or at a remote location from the photovoltaic modules 100, or system performance can be diagnosed digitally for concurrent or historical analysis, either locally or remotely relative to the photovoltaic modules 100.

Another advantage that is achieved includes that a serviceperson does not need to break the system (solar array) into many sections to find a bad section, and then find the problem module in the bad section, or take the field combiner box apart and test the circuit. Thus, advantages of the system include eliminating service time (troubleshooting a large system previously could take hours to days) and improving safety by virtue of the service person not having to break apart the system, which could present a shock hazard. Moreover, the ability to remotely evaluate a system that is not readily accessible, e.g., on the top or sides of a skyscraper, also improves safety for servicepersons.

Another advantage that is achieved includes that this system will make it easy to identify a problem module by pointing a hand held device at each module and reading the output and message. According to the present invention, the module will indicate if it has a problem.

While the present invention has been disclosed with reference to certain preferred embodiments, numerous modifications, alterations, and changes to the described embodiments are possible without departing from the sphere and scope of the present invention, as defined in the appended claims. Accordingly, it is intended that the present invention not be limited to the described embodiments, but that it have the full scope defined by the language of the following claims, and equivalents thereof.

1. An apparatus for diagnosing an under-performing photovoltaic element, the photovoltaic element functioning to convert solar energy to electricity and including a face receiving the solar energy, the apparatus comprising:
a by-pass diode electrically connected in parallel with the photovoltaic element, the by-pass diode operating between first and second states, the first operating state of the by-pass diode corresponding to a functional condition of the photovoltaic element, and the second operating state of the by-pass diode corresponding to a dysfunctional condition of the photovoltaic element; and
an indicator electrically coupled to the by-pass diode, the indicator including first and second modes, the first mode of the indicator signifying the first operating state of the by-pass diode, and the second mode of the indicator signifying the second operating state of the by-pass diode.

2. The apparatus according to claim 1, wherein the indicator is located on the face of the photovoltaic element.

3. The apparatus according to claim 1, wherein the indicator comprises a first light emitting diode.

4. The apparatus according to claim 3, wherein the light emitting diode is electrically coupled in parallel with the by-pass diode.

5. The apparatus according to claim 4, wherein the light emitting diode changes between the first and second modes in response to voltage differences between the first and second operating states of the by-pass diode.

6. The apparatus according to claim 4, wherein the light emitting diode is illuminated in the first mode and is non-illuminated in the second mode.

7. The apparatus according to claim 3, wherein the light emitting diode is electrically coupled in series with the by-pass diode.

8. The apparatus according to claim 7, wherein the light emitting diode changes between the first and second modes in response to polarity differences between the first and second operating states of the by-pass diode.

9. The apparatus according to claim 7, wherein the light emitting diode is non-illuminated in the first mode and is illuminated in the second mode.

10. The apparatus according to claim 1, wherein the indicator comprises a diagnostic circuit electrically coupled in parallel with the by-pass diode.

11. The apparatus according to claim 10, wherein the diagnostic circuit comprises measuring, identifying and sending features.

12. The apparatus according to claim 11, wherein the measuring feature comprises an analog-to-digital converter.

13. The apparatus according to claim 12, wherein the measuring feature comprises a conditioning algorithm, the by-pass diode inputting to the conditioning algorithm a first analog signal commensurate with the operating state of the by-pass diode, the conditioning algorithm outputting to the analog-to-digital converter a second analog signal scaled to a nominal voltage range, and the analog-to-digital converter outputting to the sending feature a digital signal representative of the functioning of the photovoltaic element.

14. The apparatus according to claim 11, wherein the identifying feature comprises a digital number being output to the sending feature.

15. The apparatus according to claim 14, wherein in the digital number is generally unique to the photovoltaic element.

16. The apparatus according to claim 11, wherein the sending feature consists of at least one of a wireless radio frequency transmitter and a communication wire.

17. The apparatus according to claim 10, wherein the diagnostic circuit comprises:
a conditioning algorithm, the by-pass diode inputting to the conditioning algorithm a first analog signal commensurate with the operating state of the by-pass diode;
an analog-to-digital converter, the conditioning algorithm outputting to the analog-to-digital converter a second analog signal scaled to a nominal voltage range, and the analog-to-digital converter generating a digital signal representative of the functioning of the photovoltaic element;
a digital identifier being generally unique to the photovoltaic element; and
a transmitter outputting a record including a combination of the digital signal and the digital identifier.

18. The apparatus according to claim 17, wherein the analog-to-digital converter and the transmitter are integrated on a single chip, and the conditioning algorithm and the digital identifier are stored in read-only-memory on the single chip.

19. The apparatus according to claim 18, wherein the by-pass diode and the single chip are commonly mounted on a printed circuit board.

20. The apparatus according to claim 19, wherein the transmitter comprises an antenna being etched on the printed circuit board.

21. The apparatus according to claim 17, the apparatus further comprising:
an analyzer evaluating the functioning of the photovoltaic element based the mode of the indicator.

22. The apparatus according to claim 21, wherein the analyzer comprises a receiver, an analysis algorithm, data storage and a data transmitter, the record output from the transmitter being input to the receiver, the analysis algorithm transforming the record to measurements of the functioning of the photovoltaic element and comparing the measurements with previous measurements, the data storage compiling a history of the measurements, and the data transmitter outputting the measurements.

23. The apparatus according to claim 22, wherein the transmitter modulates a radio frequency signal that is demodulated by the receiver.

24. An apparatus for diagnosing an under-performing photovoltaic element, the photovoltaic element functioning to convert solar energy to electricity, the apparatus comprising:
an electricity sensing device connected to the photovoltaic element, the electricity sensing device detecting a voltage condition of the photovoltaic element; and
an indicator electrically coupled to the device, the indicator including first and second modes, the first mode of the indicator signifying a functioning state of the photovoltaic element, and the second mode of the indicator signifying a functioning state of the photovoltaic element having not been achieved.

25. The apparatus according to claim 24, wherein the electricity sensing device comprises a by-pass diode electrically connected in parallel with the photovoltaic element.

26. The apparatus according to claim 25, wherein the indicator comprises at least one of a light emitting diode and a diagnostic circuit.

27. A photovoltaic module for mounting on a structure, the photovoltaic module comprising:
first and second module faces and an edge that extends between the first and second module faces, the first module face receiving solar energy and the second module face being adapted to generally confront the structure;
a plurality of photovoltaic cells being commonly supported by a base, each of the photovoltaic cells converting the solar energy to electricity; and
a device connected to one of the plurality of photovoltaic cells and operating between first and second states, the first operating state of the device corresponding to a functional condition of the at least one of the plurality of photovoltaic cells, and the second operating state of the device corresponding to a dysfunctional condition of the at least one of the plurality of photovoltaic cells.

28. The photovoltaic module according to claim 27, further comprising:
a plurality of the devices corresponding in number to the plurality of photovoltaic cells, each of the plurality of devices operating between first and second states, the first operating state of each of the plurality of devices corresponding to a functional condition of a corresponding one of the plurality of photovoltaic cells, and the second operating state of each of the plurality of devices corresponding to a dysfunctional condition of the corresponding one of the plurality of photovoltaic cells.

29. A system for diagnosing a photovoltaic array, the photovoltaic array including a plurality of photovoltaic elements functioning to convert solar energy to electricity, the system comprising:
a first by-pass diode electrically connected in parallel with a first one of the plurality of photovoltaic elements, the first by-pass diode operating between first and second states, the first operating state of the first by-pass diode corresponding to a functional condition of the first photovoltaic element, and the second operating state of the first by-pass diode corresponding to a dysfunctional condition of the first photovoltaic element;
a first diagnostic circuit electrically coupled to the first by-pass diode, the first diagnostic circuit including first and second modes, the first mode of the first diagnostic circuit signifying the first operating state of the first by-pass diode, and the second mode of the first diagnostic circuit signifying the second operating state of the first by-pass diode;
a second by-pass diode electrically connected in parallel with a second one of the plurality of photovoltaic elements, the second by-pass diode operating between first and second states, the first operating state of the second by-pass diode corresponding to a functional condition of the second photovoltaic element, and the second operating state of the second by-pass diode corresponding to a dysfunctional condition of the second photovoltaic element; and
a second diagnostic circuit electrically coupled to the second by-pass diode, the second diagnostic circuit including first and second modes, the first mode of the second diagnostic circuit signifying the first operating state of the second by-pass diode, and the second mode of the second diagnostic circuit signifying the second operating state of the second by-pass diode.

30. The system according to claim 29, wherein the first diagnostic circuit comprises a first transmitter and a first digital identifier being generally unique to the first photovoltaic element, the first transmitter outputting a first digital record including a combination of the first digital identifier and a first digital signal, the first digital signal being proportional to the functioning of the first photovoltaic element; and wherein the second diagnostic circuit comprises a second transmitter and a second digital identifier being generally unique to the second photovoltaic element, the second transmitter outputting a second digital record including a combination of the second digital identifier and a second digital signal, the second digital signal being proportional to the functioning of the second photovoltaic element.

31. The system according to claim 30, the system further comprising:
an analyzer receiving the first and second digital records, the analyzer including an analysis algorithm transforming the first and second digital records to corresponding independent measurements of the functioning of the first and second photovoltaic elements, respectively, and comparing the independent measurements with previous independent measurements of the corresponding first and second photovoltaic elements.

32. The system according to claim 31, wherein the analyzer comprises data storage and a data transmitter, the data storage compiling histories of the measurements, and the data transmitter outputting the measurements.

33. The system according to claim 31, wherein the first and second transmitters modulate via a radio frequency carrier the first and second digital records, and the analyzer comprises a receiver demodulating the radio frequency carrier.

34. The system according to claim 33, wherein the first and second transmitters include a time domain multiple access scheme to share the radio frequency carrier.

35. A method of evaluating performance of a photovoltaic array including a plurality of photovoltaic elements, each of the photovoltaic elements functioning to convert solar energy to electricity, the method comprising:
diagnosing independently the functioning of individual photovoltaic elements, the diagnosing including a separate diagnostic circuit for each of the individual photovoltaic elements; and
identifying under-performing individual photovoltaic elements within the photovoltaic array, the identifying including analyzing contemporary and historical measurements of the individual photovoltaic elements.

36. The method according to claim 35, wherein the diagnosing is performed locally with respect to the individual photovoltaic elements, and the identifying is performed remotely with respect to the individual photovoltaic elements.

37. A method of monitoring individual performance of each of a plurality of photovoltaic elements, each of the plurality of photovoltaic elements function to convert solar energy to electricity, the method comprising:
evaluating individually a status of each of the plurality of photovoltaic elements;
communicating the status of each of the plurality of photovoltaic elements; and
analyzing performance of each of the plurality of photovoltaic elements.

38. The method according to claim 37, wherein the analyzing comprises determining a set of the plurality of photovoltaic elements that are not achieving a desired function; and
servicing the set of the plurality of photovoltaic elements based on the analyzing.

39. The method according to claim 38, wherein the analyzing comprises sending the set of the plurality of photovoltaic elements to a remote location.
